(19) United States
(12) Patent Application Publication
(10) Pub. No.: US 2008/0197466 A1
(43) Pub. Date: Aug. 21, 2008

(54) SEMICONDUCTOR DEVICE AND MANUFACTURING METHOD THEREOF

(75) Inventors: Ryuji NOMOTO, Kawasaki (JP); Yoshitaka AIBA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/111,379

(22) Filed: Apr. 29, 2008

Related U.S. Application Data
(63) Continuation of application No. PCT/JP2005/021091, filed on Nov. 17, 2005.

(51) Int. Cl. H01L 23/495

(52) U.S. Cl. 257/676

(57) ABSTRACT

A semiconductor device includes: a semiconductor chip; a plurality of pellet-like electrically conductive members connected to electrodes of the semiconductor chip; and an encapsulation resin that encapsulates the semiconductor chip and the electrically conductive members. The electrically conductive members are embedded into the encapsulation resin. Surfaces of the electrically conductive members are exposed from the encapsulation resin so that the electrically conductive members serve as external connection terminals of the semiconductor device.

### CROSS-REFERENCE TO THE RELATED APPLICATION

This application is a U.S. continuation application, filed under 35 USC 111(a) and claiming the benefit under 35 USC 120 and 365(c), of PCT application JP2005/021091 filed Nov. 17, 2005. The foregoing application is hereby incorporated herein by reference.

### BACKGROUND OF THE INVENTION

1. Field of the Invention

The present invention relates to a semiconductor device and a manufacturing method thereof and, more particularly, to a surface-mount type semiconductor device having no substrate (die stage) on which a semiconductor chip is mounted and a manufacturing method thereof.

2. Description of Related Art

In recent years, with further miniaturization of portable electronic equipments, such as a cellular phone or a notebook-type personal computer, semiconductor devices constituting electronic circuits in those electronic equipments are demanded with further miniaturization. Additionally, in order to reduce a mount area thereof, a so-called surface-mount type package structure has been applied to the semiconductor devices concerned.

In such a surface-mount type semiconductor device, a unified package form and outside configuration has not been used, and various kinds of package structures and manufacturing methods thereof have been suggested even in a semiconductor device having external connection terminals of less than 100 pins.

As a manufacturing method of a semiconductor device having small number of external connection terminals, there is a method comprising: mounting a plurality of semiconductor chips on a lead frame; connecting electrodes of the semiconductor chip and portions of the lead frame that are made into terminals by bonding wires; after resin-encapsulation, electrically separating the terminals of the lead frame by etching or the like; and individualizing packages by dicing or the like. In this manufacturing method, it is needed to prepare lead frames having different patterns for each kind of the semiconductor chip, thereby increasing a cost of the semiconductor device by a corresponding cost associated with the lead frame.

Thus, there is suggested a manufacturing method of a semiconductor device, comprising: after forming terminal portions by patterning by etching a metal foil applied onto an adhesive sheet, mounting a semiconductor chip on the adhesive sheet; electrically connecting electrodes of the semiconductor chip to electrodes formed by the metal foil on the adhesive sheet; and separating the adhesive sheet after resin-encapsulating the semiconductor chip (for example, refer to Patent Document 1).

According to this manufacturing method, because patterning is performed by etching the metal foil, the etching process takes a long time, and a mask for etching must be prepared for each kind of semiconductor chips. Additionally, it requires a process such as metal-plating on the metal foil after the etching process so as to acquire a sufficient thickness as an electrode, which results in a cost increase.

Although the Patent Document 1 suggests applying a previously press-formed metal foil to an adhesive sheet instead of forming electrodes by etching the metal foil, a mold for press-forming must also be prepared for each kind of semiconductor chips.

On the other hand, there is suggested a method comprising: fixing electrode members and a semiconductor chip by fitting them into concave portions formed in a metal made holding substrate; connecting electrodes of the semiconductor chips and the electrode members by bonding-wires on the holding substrate; and eliminating the holding substrate after resin encapsulation (for example, refer to Patent Document 2). In this manufacturing method, there is no need to process the electrode members on the holding substrate. However, it is required to form the concave portions on the holding substrate so as to fix the electrode members by fitting them into the concave portions. Thus, the holding substrate must be prepared for each kind of semiconductor chips.

Patent Document 1: Japanese Laid-Open Patent Application No. 2004-63615

Patent Document 2: Japanese Laid-Open Patent Application No. 11-3953

As mentioned above, also in each of the manufacturing methods of the Patent Document 1 and the Patent Document 2, if the sizes of the semiconductor chips and the number and arrangement of the electrode terminals vary from one semiconductor chip to another, the same mold or the same holding substrate cannot be used. That is, it is required to prepare the mold or the holding substrate for each kind of semiconductor chips to be mounted. Thus, there is a problem that a manufacturing cost of the semiconductor device is increased by a cost corresponding to the preparation of the molds or holding substrates.

### SUMMARY

According to an aspect of an embodiment, there is provided a semiconductor device comprising: a semiconductor chip; a plurality of pellet-like electrically conductive members connected to electrodes of the semiconductor chip; and an encapsulation resin part that encapsulates the semiconductor chip and the electrically conductive members, wherein the electrically conductive members are embedded into the encapsulation resin part, and surfaces of the electrically conductive members are exposed from the encapsulation resin part so that the electrically conductive members serve as external connection terminals of the semiconductor device.

According to another aspect of the embodiment, there is provided a manufacturing method of a semiconductor device, comprising: arranging at least one semiconductor chip and a plurality of pellet-like electrically conductive members on a pressure sensitive tape; connecting the semiconductor chip and the electrically conductive members to each other on the pressure sensitive tape; encapsulating the semiconductor chip and the electrically conductive members by an encapsulation resin part on the pressure sensitive tape; and thereafter, removing the pressure sensitive tape from the encapsulation resin part.

Further, there is provided a manufacturing method of a semiconductor device, comprising: arranging a plurality of pellet-like electrically conductive members on a pressure sensitive tape; connecting electrodes of a semiconductor chip to said electrically conductive members on the pressure sensitive tape; encapsulating the semiconductor chip and the electrically conductive members by an encapsulation resin part on the pressure sensitive tape; and thereafter, removing the pressure sensitive tape from the encapsulation resin part.

Additionally, because no lead frame is used, the thickness (height) of the semiconductor device cab be reduced, which provides the semiconductor device having further reduced thickness.

Further, also because the pellet-like electrically conductive members, which are made into external connection terminals (mounting terminals), are in a state where they are embedded in a encapsulation resin and the electrically conductive members do not protrude from the encapsulation resin, the thickness (height) of the semiconductor device can be reduced.

Other objects, features and advantages of the present invention will become more apparent from the following detailed description when read in conjunction with the accompanying drawings.

### BRIEF DESCRIPTION OF THE DRAWINGS

FIG. 1 is a view of a semiconductor device according to a first embodiment in a middle of a manufacturing process;

FIGS. 2A through 2C are views showing parts of the manufacturing process of the semiconductor device according to the first embodiment;

FIGS. 3A through 3C are views showing parts of the manufacturing process of the semiconductor device according to the first embodiment;

FIGS. 4A through 4C are views showing parts of the manufacturing process of the semiconductor device according to the first embodiment;

FIG. 5 is a cross-sectional view of a semiconductor device in which an alignment pellet remains;

FIG. 6 is a cross-sectional view of a semiconductor device using a semiconductor chip having electrodes of a dual-row arrangement;

FIG. 7 is a cross-sectional view of a semiconductor device when a heat-radiation plate is arranged under a semiconductor chip;

FIG. 8 is a cross-sectional view of a semiconductor device having heat-radiation pellets provided under a semiconductor chip;

FIG. 9 is a cross-sectional view showing an example of a semiconductor device, which is formed by stacking a semiconductor chip on another semiconductor chip;

FIG. 10 is a cross-sectional view showing a case where pellets having a large thickness are provided in the semiconductor device shown in FIG. 9;

FIG. 11 is a cross-sectional view of a semiconductor device having two semiconductor chips arranged two-dimensionally;

FIG. 12 is a perspective view of the semiconductor device shown in FIG. 11 in a middle of the manufacturing process;

FIG. 13 is a cross-sectional view of a semiconductor device having two semiconductor chips arranged two-dimensionally and another semiconductor chip for relay arranged between the two semiconductor chips;

FIG. 14 is a perspective view of the semiconductor device shown in FIG. 13 in a middle of the manufacturing process;

FIG. 15 is a perspective view of a semiconductor device having a capacitor connected between power terminals of a semiconductor chip in a middle of the manufacturing process;

FIG. 16 is a cross-sectional view of a semiconductor device according to a second embodiment;

FIG. 17 is a cross-sectional view of the semiconductor device shown in FIG. 16 having a heat-radiation plate attached thereto; and

FIG. 18 is a cross-sectional view of the semiconductor device shown in FIG. 16 in a state where a heat-radiation plate is embedded in an encapsulation resin.

### DETAILED DESCRIPTION OF THE PREFERRED EMBODIMENTS

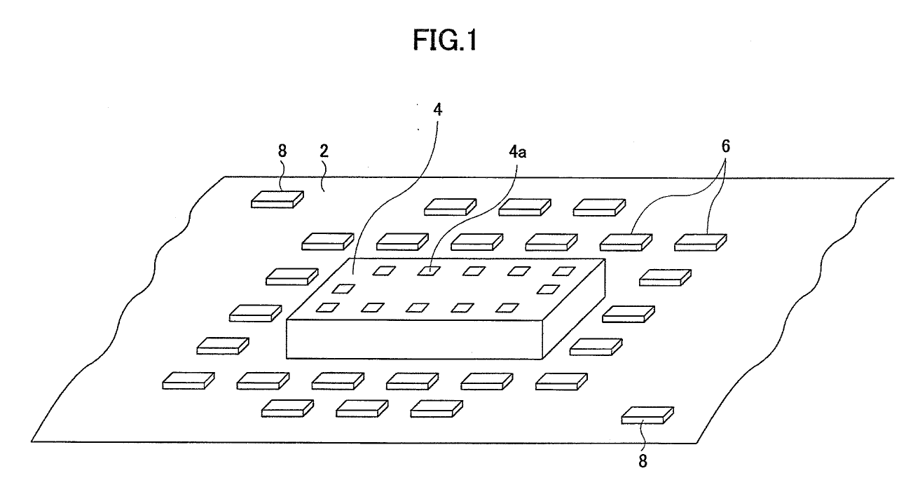

A description will now be given, with reference to the drawings, of a semiconductor device according to a first embodiment and a manufacturing method of the semiconductor device according to the first embodiment. FIG. 1 shows a state where a semiconductor chip is mounted on a pressure sensitive tape in the manufacturing method according to the first embodiment.

In the manufacturing method according to the first embodiment, as shown in FIG. 1, the pressure sensitive tape 2 is used as a support member for supporting the semiconductor chip 4. The semiconductor chip 4 is mounted onto the pressure sensitive tape 2 in a face-up state (a circuit formation surface facing upward). A plurality of terminal pellets 6, which are made into external connection terminals of the semiconductor device, are arranged around the semiconductor chip 4. Each terminal pellet 6 is formed of a pellet-like electrically conductive member such as, for example, a rectangular parallelepiped metal piece. The semiconductor chip 4 and the terminal pellets 6 are fixed on the pressure sensitive tape 2 due to tackiness of the pressure sensitive tape 2.

The terminal pellets 6 can be electrically connected to respective electrodes 4 of the semiconductor chip 4 according to a wire-bonding method, as mentioned later. The semiconductor device according to the present embodiment is formed on the pressure sensitive resin 2 by encapsulating the semiconductor chip 4 and the terminal pellets 6 by an encapsulation resin on the pressure sensitive tape 2. Thereafter, the pressure sensitive tape 2 is exfoliated and removed from an encapsulation resin part. Thus, surfaces of the terminal pellets 6 are exposed from the encapsulation resin part, which makes the terminal pellets 6 into external connection terminals (mounting terminals) of the semiconductor device.

The pressure sensitive tape 2 can be a tape having tackiness, such as a dicing tape or a back-grind tape that is normally used in a semiconductor manufacturing process. That is, the pressure sensitive tape 2 includes a resin tape base and a tacking material layer provided on one side of the resin tape base. Because a wire-bonding process is performed on the pressure sensitive tape 2, the pressure sensitive tape 2 must have a heat resistance so that the pressure sensitive tape 2 is not deformed due to heat during the wire-bonding process. Also, the pressure sensitive tape 2 must have a heat resistance so that the pressure sensitive tape 2 is prevented from being deformed due to heat when the encapsulation resin part is formed on the pressure sensitive tape 2.

The terminal pellet 6, which is a pellet-like electrically conductive member serving as an external connection terminal (mounting terminal) of the semiconductor device, is made of a metal such as, for example, copper (Cu) or aluminum (Al). The terminal pellet 6 has a thickness of, for example, 0.1 mm so that the terminal pellet 6 is prevented from being deformed due to a pressing force applied when the wire-bonding process is performed. Although the terminal pellet 6 generally has a rectangular parallelepiped shape such as shown in FIG. 1, the shape of the terminal pellet 6 is not limited to the rectangular parallelepiped shape and can be a cubic shape, a polygonal column shape, or a spherical shape, if needed.

It is preferable that the surfaces of the terminal pellet 6 are plated previously by metal such as, for example, gold (Au), silver (AG) or palladium (Pd). That is, because the surface of the terminal pellet 6 that is stuck onto the pressure sensitive tape 2 must serve as an external connection terminal (mounting terminal) by being exposed finally, the surface of the terminal pellet 6 is preferably metal-plated so as to acquire wetness to a solder or the like.

Moreover, since a bonding-wire is connected to the surface of the terminal pellet 6 facing upward when the terminal pellet 6 is stuck onto the pressure sensitive tape 2, it is preferable to apply a metal-plating process so that the bonding-wire is easily bonded to the surface of the terminal pellet 6. Although the metal-plating may be applied to all surfaces of the terminal pellet 6, metal-plating may be applied only to the surface to which the bonding-wire is bonded and the surface to be exposed to serve as an external connection terminal (mounting terminal). It should be noted that the pellet-like electrically conductive member constituting the terminal pellet 6 is not necessarily made of a metal, and the terminal pellet 6 may be made of other materials having a good conductivity and a necessary rigidity.

In the structure shown in FIG. 1, alignment pellets 8 are arranged around an area where the terminal pellets 6 are arranged. Each alignment pellet 8 indicates a reference position used when applying the semiconductor chip 4 and the terminal pellets 6 to the pressure sensitive tape 2. The alignment pellets 8 are used as a position recognition mark when individualizing the semiconductor device by dicing after resin encapsulation. The alignment pellet 8 does not need to have an electrical conductivity because the alignment pellet 8 is used for position recognition. Thus, the alignment pellet 8 may be made of a material different from the material of the terminal pellet 6, but the same material may be used for both the terminal pellet 6 and the alignment pellet 8.

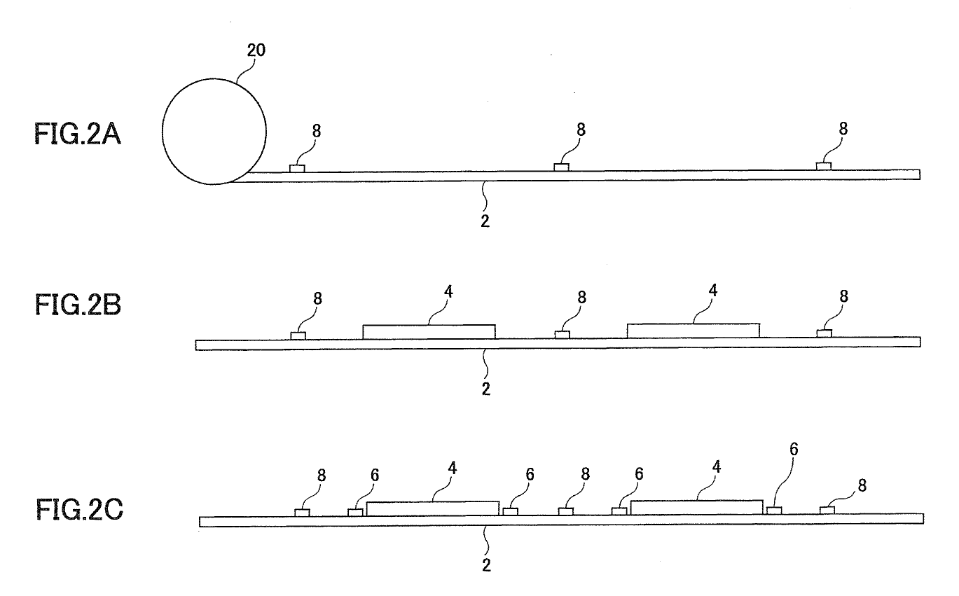

A description will be given below, with reference to FIG. 2 through FIG. 4, of a manufacturing process to provide the semiconductor chip 4 and the terminal pellets 6 on one side of the pressure sensitive tape 2 used as a base. In the manufacturing method mentioned below, the pressure sensitive tape 2 is formed in a belt-like shape so as to be supplied in a state where the pressure sensitive tape 2 is wound on a real.

First, as shown in FIG. 2A, the pressure sensitive tape 20 is taken out of an IN-side real 20, and the alignment pellets 8 are stuck onto the sticky surface of the pressure sensitive tape 2 by using a die bonder (not shown in the figure). Then, as shown in FIG. 2B, the semiconductor chips 4 are stuck by using a die bonder (not shown in the figure). At this time, the semiconductor chips 4 are mounted on the pressure sensitive tape 2 with their circuit formation surfaces facing upward. Thus, the back surfaces of the semiconductor chips 4 are stuck to the pressure sensitive tape 2. The positions of the semiconductor chips 4 on the pressure sensitive tape 2 are determined based on the alignment pellets 8 used as a reference position.

Then, as shown in FIG. 2C, the terminal pellets 6 are stuck to the sticky surface of the pressure sensitive tape 2 around the semiconductor chips 4 by using a die bonder (not shown in the figure). The positions of the terminal pellets 6 are also determined based on the alignment pellets 8 used as a reference position. It should be noted that the order of mounting the semiconductor chips 4 and the terminal pellets 6 onto the pressure sensitive tape 2 may be changed.

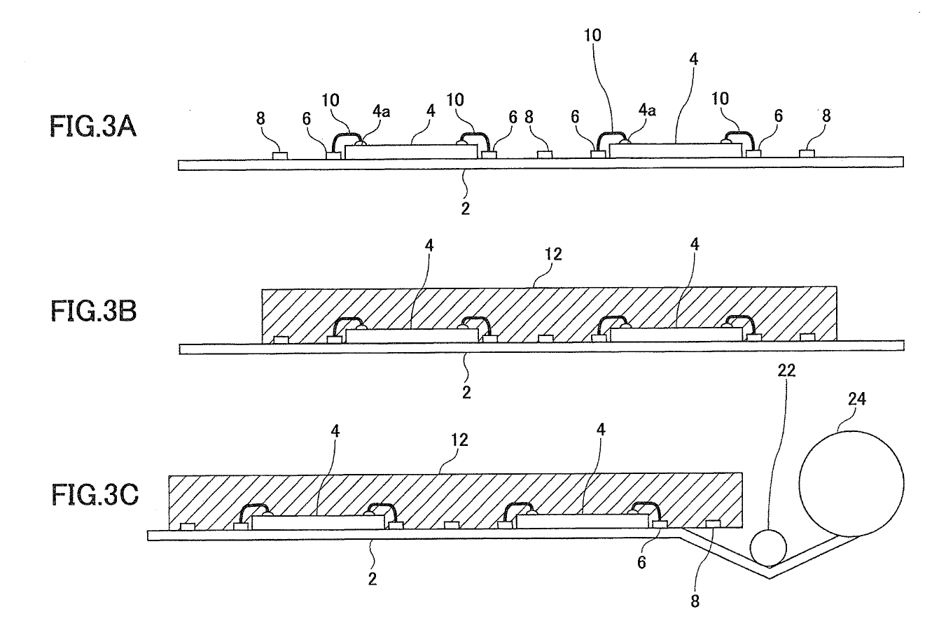

Thereafter, as shown in FIG. 3A, the electrode terminals 4a of the semiconductor chips 4 and the corresponding terminal pellets 6 are electrically connected to each other by bonding-wires 10. Then, as shown in FIG. 3B, the semiconductor chips 4, the terminal pellets 6 and the bonding-wires 10 on the pressure sensitive tape 2 are encapsulated by an encapsulation resin, thereby forming an encapsulation resin part 12. In the present embodiment, the plurality of semiconductor chips 4 and the plurality of terminal pellets 6 are encapsulated together at once so as to form a plurality of semiconductor devices together. When forming a single semiconductor device on the pressure sensitive tape 2, a single semiconductor chip 4 and a plurality of terminal pellets 6 surrounding the single semiconductor chip 4 may be encapsulated together. The encapsulation resin part 12 can be formed by transfer molding by placing a mold on the pressure sensitive tape 2. Such an encapsulation is not limited to the transfer molding, and other methods such as a print encapsulation method or a potting encapsulation method may be used.

In the present embodiment, the two semiconductor chips 4 and the terminal pellets 6 surrounding the two semiconductor chips 4 are encapsulated together at once. However, the number of the semiconductor chips 4 encapsulated together is not limited to two, and, if possible, more than three semiconductor chips 4 may be encapsulated together at once. Additionally, a plurality of semiconductor chips 4 may be arranged in a direction of a width of the pressure sensitive tape 2 so as to encapsulate the semiconductor chips 4 and the terminal pellets 6 surrounding the semiconductor chips 4 together at once. Or, the semiconductor chip 4 on the pressure sensitive tape 2 and a semiconductor chip on another pressure sensitive tape arranged in a direction of a with of the pressure sensitive tape 2 may be encapsulated together in one encapsulation resin part.

After encapsulating the semiconductor chips 4, as shown in FIG. 3C, the pressure sensitive tape 2 is exfoliated and removed from the encapsulation resin part 12. The exfoliation of the pressure sensitive tape 2 can be carried out by changing a moving direction of the pressure sensitive tape 2 into a direction of separating the pressure sensitive tape 2 from the encapsulation resin part 12. The pressure sensitive tape 2 separated from the encapsulation resin part 12 is wound on an OUT-side real 24.

The above-mentioned processes are carried out as a series of processes while the pressure sensitive tape 2 is taken out of the IN-side real 20 and is wound on the OUT-side real 24. The pressure sensitive tape 2 may be stopped at each process so that mounting of the semiconductor chips and terminal pellets, wire-bonding, resin encapsulation, etc., are performed when the pressure sensitive tape 2 is stopped.

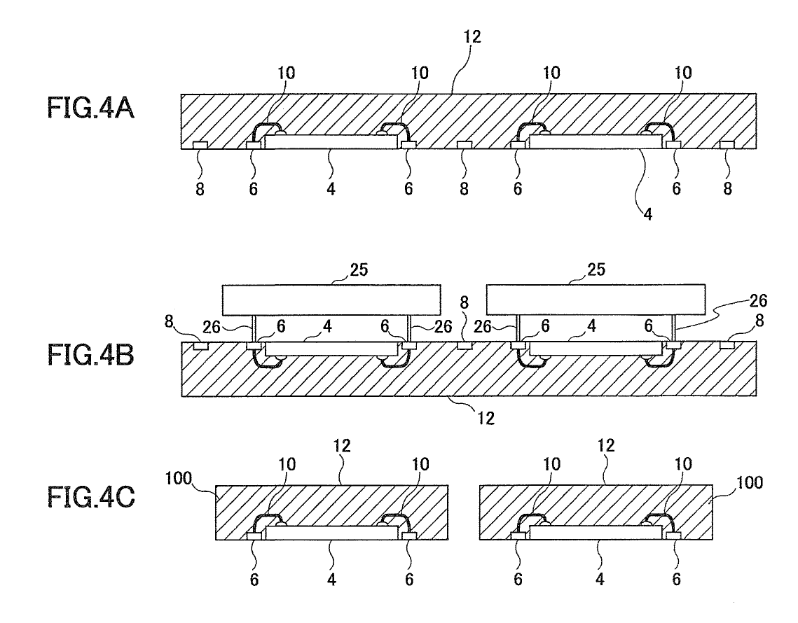

The encapsulation resin part 12 separated from the pressure sensitive tape 2 is subjected to a curing process of the encapsulation resin, as shown in FIG. 4A, by being left at a room temperature or being heated at an elevated temperature. In this state, the encapsulation resin part 12 contains the two semiconductor chips 4, the corresponding terminal pellets 6, the bonding-wires 10 and the alignment pellets 8.

After the encapsulation resin is cured, an electric characteristic test is performed on the semiconductor chips 4. The electric characteristic test is performed, as shown in FIG. 4B, by contacting probe needles 26 of probe cards 25 to the terminal pellets 6 exposed from the encapsulation resin part 12.

After the electric characteristic test is completed, the encapsulation resin part 12 is cut by a cutting blade so as to individualize each semiconductor device as shown in FIG. 4C, thereby forming a plurality of semiconductor devices 100. At this time, the dicing line along which the encapsulation resin part 12 is cut is determined based on the alignment pellets 8 exposed from the encapsulation resin part 12. In the present embodiment, the alignment pellets 8 are arranged on the dicing line so that the alignment pellets 8 are removed when dicing the encapsulation resin part 12, as shown in FIG. 4B and FIG. 4C.

As mentioned above, in the semiconductor device and the manufacturing process of the semiconductor device according to the present embodiment, a lead frame or the like is not used and at least one semiconductor chip 4 and the terminal pellets 6 are stuck to the pressure sensitive tape 2, and, thereafter, the semiconductor chip 4 is electrically connected to terminal pellets 6 and encapsulated by the encapsulation resin so as to form the semiconductor device. Accordingly, there is no need to prepare a lead frame, which must be prepared for each kind of semiconductor chips, and different kinds of semiconductor chips can be handled in one manufacturing process, which reduces a manufacturing cost of the semiconductor devices. Additionally, the thickness of the semiconductor device can be reduced by a part corresponding to the eliminated lead frame, which provides a thinner semiconductor device.

In the semiconductor device manufactured by the manufacturing method according to the present embodiment, the terminal pellets 6 that are used as external connection terminals (mounting terminals) are in a state where each of the terminal pellets 6 is entirely embedded in the encapsulation resin part 12. That is, each of the terminal pellets 6 does not protrude from the bottom surface of the encapsulation resin part 12 and only one surface serving as an external connection part is exposed outside. Thus, also in this respect, the thickness of the semiconductor device can be reduced.

Additionally, the terminal pellets 6 are formed by not processing a metal plate or a metal foil into a plurality of terminals in a manufacturing process of the semiconductor device but prepared previously as the pellet-like electrically conductive members and supplied to the manufacturing process. That is, the terminal pellets 6 made into external connection terminals (mounting terminals) are not formed in the manufacturing process of the semiconductor device. In this respect, the semiconductor device according to the present embodiment differs from a semiconductor device manufactured by a conventional manufacturing method in the structure and configuration of the external connection terminals (mounting terminals).

It should be noted that although the alignment pellets 8 are eliminated when dicing the encapsulation resin part 12 in the semiconductor device 100 shown in FIG. 4C, the alignment pellets 8 are not always be eliminated and may be remained in the completed semiconductor device as shown in FIG. 5.

A description will now be given of variations of the semiconductor device according to the above-mentioned embodiment.

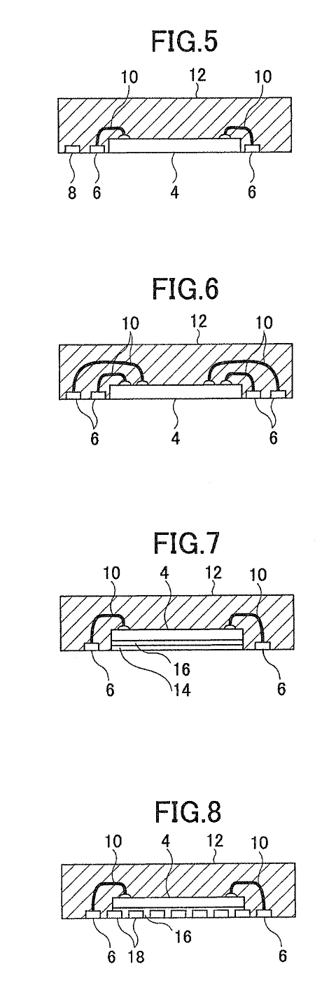

FIG. 6 shows a structure of a semiconductor device using a semiconductor chip 4 having electrode terminals arranged in two rows. The terminal pellets 6 serving as external connection terminals (mounting terminals) are arranged in two rows in the peripheral portion of the semiconductor chip 4. In such a case where the number of the external connection terminals is large and the terminal pellets 6 can not be arranged in a single row in the peripheral portion of the semiconductor chip 4, the terminal pellets 6 may be arranged in a plurality of rows within an area where the wire-bonding can be performed.

FIG. 7 shows a structure of a semiconductor device having a heat-radiation plate 14 under the semiconductor chip 4. The heat-radiation plate 14 is stuck to the pressure sensitive tape 2 at a position where the semiconductor chip 4 is mounted before the semiconductor chip 4 is mounted. The semiconductor chip 4 is fixed to the heat-radiation plate 14 by an adhesive 16.

It should be noted that a plurality of heat-radiation pellets 18 may be provided as a heat-radiating member under the semiconductor chip 4 instead of the heat-radiation plate 14. The heat-radiation pellets 18 must be made of a material having a good thermal conductivity. If the terminal pellets 6 or the alignment pellets 8 have a good thermal conductivity, the heat-radiation pellets 18 may be made of the same material as the terminal pellets 6 or the alignment pellets 8.

A description will now be given of examples of a semiconductor device having a plurality of semiconductor chips incorporated therein.

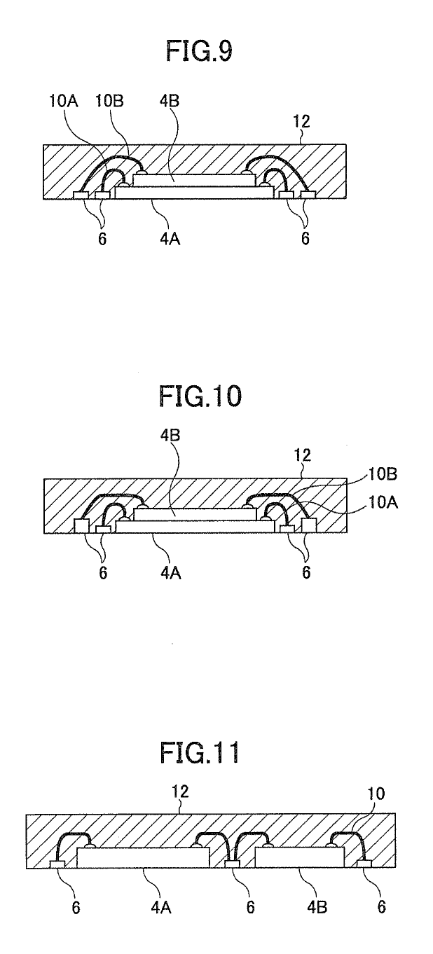

FIG. 9 shows an example in which a semiconductor device is formed by stacking a second semiconductor device 4B on a first semiconductor device 4A. Because the semiconductor chip 4B is arranged on a circuit formation surface of the semiconductor chip 4A, the semiconductor chip 4B is smaller than the semiconductor chip 4A. In a case where bonding-wires 10B of the semiconductor chip 4B may contact with bonding-wires 10A of the semiconductor chip 4A, the bonding-wires 10A and 10B may be prevented from contacting with each other by increasing the height of the terminal pellets 6 to which the bonding-wires 10B are bonded so as to maintain a large distance (clearance) between the bonding-wires 10A and 10B.

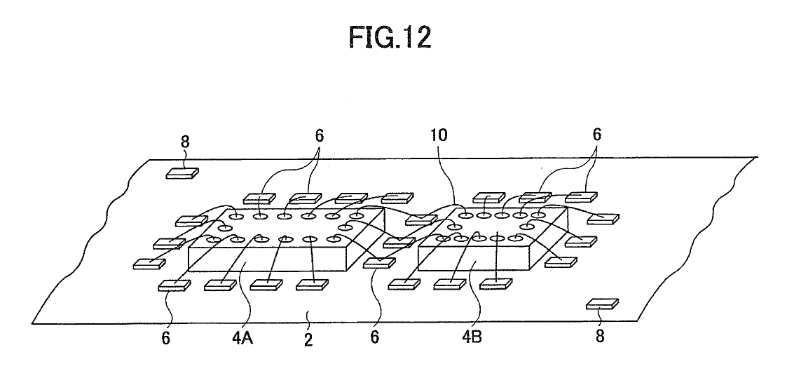

FIG. 11 shows an example of a semiconductor device having two semiconductor chips arranged in the same plane. FIG. 12 shows the semiconductor device shown in FIG.11 in a middle of the manufacturing process. In the semiconductor device shown in FIG. 11, the semiconductor chip 4A and the semiconductor chip 4B are arranged on the pressure sensitive tape 2 side by side, and the terminal pellets 6 are arranged between the semiconductor chip 4A and the semiconductor chip 4B. The electrode terminals of the semiconductor chip 4A and the electrode terminal of the semiconductor chip 4B are mutually connected via the terminal pellets 6, and a connection to terminals of the corresponding potential can be made in common.

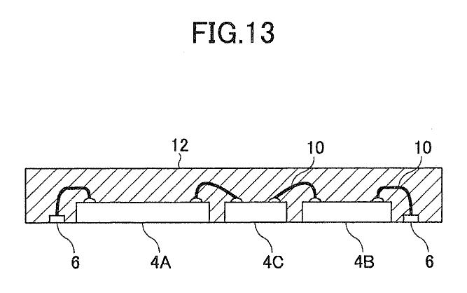

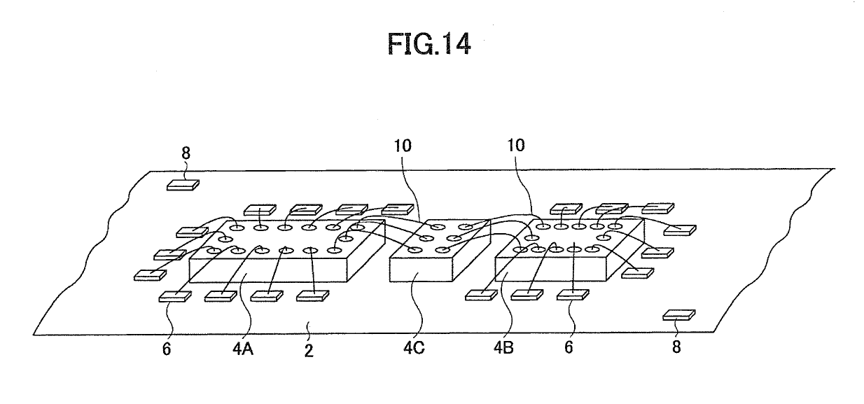

FIG. 13 shows an example of a semiconductor device in which two semiconductor chips are arranged two-dimensionally and a semiconductor chip for relay is arranged between the two semiconductor chips. FIG. 14 shows the semiconductor device shown in FIG. 13 in a middle of a manufacturing process. In the semiconductor device shown in FIG. 13, a semiconductor chip 4C for relay is provided between the semiconductor chip 4A and the semiconductor chip 4B so as to interface the semiconductor chip 4A and the semiconductor chip 4B. The semiconductor chip 4C has electrodes to be connected to the semiconductor chip 4A and electrodes to be connected to the semiconductor chip 4B. A relay board (terminal chip) may be provided instead of the semiconductor chip 4C for relay.

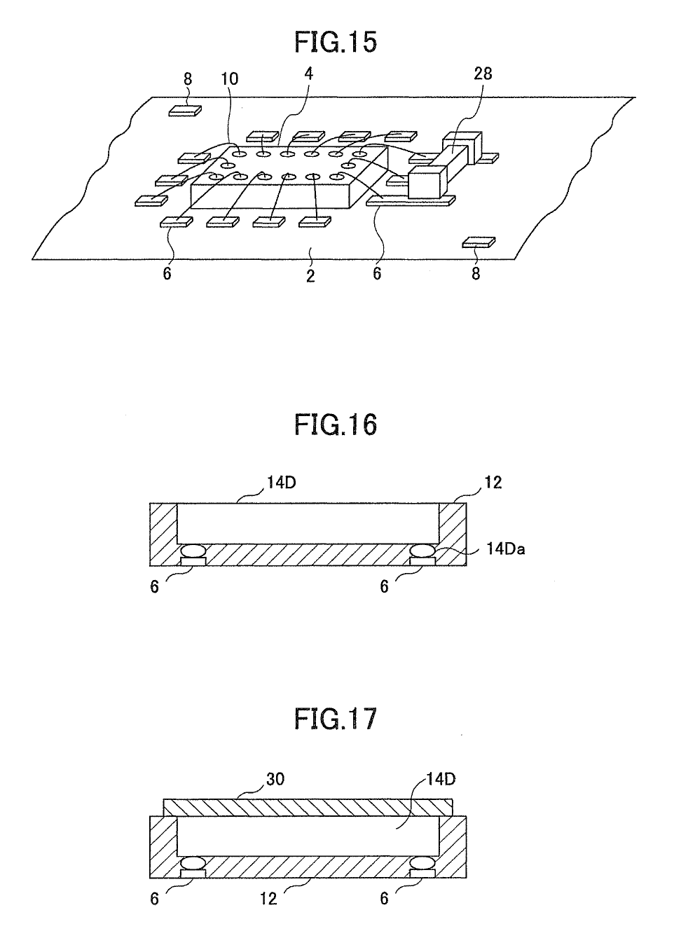

FIG. 15 shows a semiconductor device having a capacitor 28 connected between a power supply terminal and a grounding terminal of the semiconductor chip 4 in a middle of the manufacturing process. A passive element such as a capacitor, a resistor or an inductor can be incorporated into the semiconductor device by mounting and fixing to the terminal pellets 6.

A description will be given below, with reference to FIG. 16 through FIG. 18, of a semiconductor device according to a second embodiment. The semiconductor device according to the second embodiment has a semiconductor chip 4D that is flip-chip connected to the terminal pellets 6 arranged on the pressure sensitive tape 2.

When manufacturing the semiconductor device shown in FIG. 16, the terminal pellets 6 are stuck onto the pressure sensitive tape 2 by using the alignment pellets 8 as a position reference in the same manner as the above-mentioned manufacturing method of the semiconductor device according to the first embodiment. At this time, the terminal pellets 6 are arranged at positions corresponding to protruding electrodes 4Da (gold bumps, solder bumps, etc.) of the semiconductor chip 4D to be mounted. Then, the protruding electrodes 4Da of the semiconductor chip 4D are bonded to the terminal pellets 6 with the circuit formation circuit facing downward.

After flip-chip connecting the semiconductor chip 4D, the semiconductor chip 4D is encapsulated on the pressure sensitive tape 2. At this time, as shown in FIG. 16, the back surface of the semiconductor chip 4D may be exposed from the encapsulation resin part 12 so as to improve the heat-radiation efficiency and reduce a thickness of the semiconductor device. After the encapsulation, the pressure sensitive tape 2 is removed from the encapsulation resin part 12, which results in exposure of the surfaces of the terminal pellets 6.

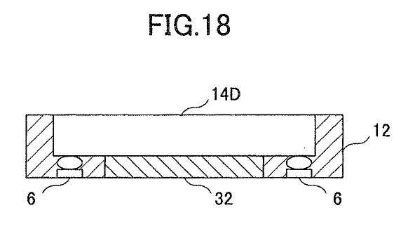

In the above-mentioned semiconductor device, a heat-radiation plate 30 may be attached to the back surface of the semiconductor chip 4D as shown in FIG. 17 so as to further improve the heat-radiation efficiency. Alternatively, as shown in FIG. 18, a heat-radiation plate 32 may be provided under the semiconductor chip 4D (circuit formation surface side) so as to embed the heat-radiation plate 32 into the encapsulation resin part 12. In this case, if the heat-radiation plate 32 is stuck to the pressure sensitive tape 2 before flip-chip connecting the semiconductor chip 4D in the manufacturing process, the heat-radiation plate 32 can be embedded into the encapsulation resin part 12.

The present invention is not limited to the specifically disclosed embodiments, and variations and modifications may be made without departing from the scope of the present invention.

What is claimed is:

1. A semiconductor device comprising:
a semiconductor chip;
a plurality of pellet-like electrically conductive members connected to electrodes of the semiconductor chip; and
an encapsulation resin part that encapsulates said semiconductor chip and said electrically conductive members,
wherein said electrically conductive members are embedded into said encapsulation resin part, and surfaces of said electrically conductive members are exposed from said encapsulation resin part so that said electrically conductive members serve as external connection terminals of said semiconductor device.

2. The semiconductor device as claimed in claim 1, wherein the electrodes of said semiconductor chip and said electrically conductive members are connected to each other by bonding-wires.

3. The semiconductor device as claimed in claim 1, wherein said semiconductor chip is flip-chip connected to said electrically conductive members.

4. The semiconductor device as claimed in claim 1, wherein the surfaces of said electrically conductive members are plated.

5. A manufacturing method of a semiconductor device, comprising:
arranging at least one semiconductor chip and a plurality of pellet-like electrically conductive members on a pressure sensitive tape;
connecting said semiconductor chip and said electrically conductive members to each other on said pressure sensitive tape;
encapsulating said semiconductor chip and said electrically conductive members by an encapsulation resin part on said pressure sensitive tape; and
thereafter, removing said pressure sensitive tape from said encapsulation resin part.

6. The manufacturing method as claimed in claim 5, wherein the electrodes of said semiconductor chip and said electrically conductive members are connected to each other by a wire-bonding method.

7. The manufacturing method as claimed in claim 5, further comprising:
arranging an alignment member on said pressure sensitive tape; and
arranging said semiconductor chip and/or said electrically conductive members on said pressure sensitive tape using the alignment member as a reference.

8. The manufacturing method as claimed in claim 5, further comprising:
curing said encapsulation resin part after removing said pressure sensitive tape; and
performing an electric test on said semiconductor device.

9. The manufacturing method as claimed in claim 5, further comprising:
forming a plurality of semiconductor devices into one piece by arranging a plurality of semiconductor devices on said pressure sensitive tape;
performing an electric test on said plurality of semiconductor devices together; and
thereafter, individualizing each semiconductor device.

10. A manufacturing method of a semiconductor device, comprising:
arranging a plurality of pellet-like electrically conductive members on a pressure sensitive tape;
connecting electrodes of a semiconductor chip to said electrically conductive members on said pressure sensitive tape;
encapsulating said semiconductor chip and said electrically conductive members by an encapsulation resin part on said pressure sensitive tape; and
thereafter, removing said pressure sensitive tape from said encapsulation resin part.

11. The manufacturing method as claimed in claim 10, wherein said semiconductor chip is flip-chip connected to said electrically conductive members.

12. The manufacturing method as claimed in claim 10, further comprising:
arranging an alignment member on said pressure sensitive tape; and
arranging said semiconductor chip and/or said conductive members on said pressure sensitive tape using the alignment member as a reference.

13. The manufacturing method as claimed in claim 10, further comprising:
curing said encapsulation resin part after removing said pressure sensitive tape; and
performing an electric test on said semiconductor device.

14. The manufacturing method as claimed in claim 10, further comprising:
forming a plurality of semiconductor devices into one piece by arranging a plurality of semiconductor devices on said pressure sensitive tape;
performing an electric test on said plurality of semiconductor devices together; and
thereafter, individualizing each semiconductor device.
